(19) United States
(12) Patent Application Publication
(10) Pub. No.: US 2014/0132905 A1
(43) Pub. Date: May 15, 2014

(54) ARRAY SUBSTRATE AND MANUFACTURE METHOD OF THE SAME, LIQUID CRYSTAL DISPLAY PANEL, AND DISPLAY DEVICE

(71) Applicant: BOE TECHNOLOGY GROUP CO., LTD., Beijing (CN)

(72) Inventors: Chunfang ZHANG, Beijing (CN); Hee cheol KIM, Beijing (CN); Yan WEI, Beijing (CN); Chao XU, Beijing (CN)

(73) Assignee: BOE TECHNOLOGY GROUP CO., LTD., Beijing (CN)

(21) Appl. No.: 14/071,695

(22) Filed: Nov. 5, 2013

(30) Foreign Application Priority Data
Nov. 12, 2012 (CN) 201210450894.5

(51) Int. Cl. H01L 29/786; H01L 29/66

(52) U.S. Cl. CPC H01L 29/786; H01L 29/66742
USPC 349/139; 257/49; 438/151

(57) ABSTRACT

The present invention relates to an array substrate and a manufacture method of the same, a liquid crystal display panel, and a display device, which are relative to a liquid crystal display field. Further, source electrodes and drain electrodes of the array substrate are arranged on different layers. In the manufacture method of the array substrate, the source electrodes and the drain electrodes are formed on different layers by two patterning processes. According to the technical scheme of the present invention, a length of a channel between the source electrodes and the drain electrodes can be decreased as much as possible, thereby increasing a start current Iₒₙ of a TFT.

### CROSS REFERENCE

This application claims priority to CN 201210450894.5, filed Nov. 12, 2012, which is hereby incorporated by reference.

### BACKGROUND OF THE INVENTION

1. Field of the Invention

The present invention relates to liquid crystal display field, particularly relates to an array substrate and a manufacture method of the same, a liquid crystal display panel, and a display device.

2. Description of the Prior Art

A on-state current Iₒₙ is an important parameter of a Thin Film Transistor-Liquid Crystal Display (TFT-LCD), and the on-state current Iₒₙ affects a display quality of the TFT-LCD. Nowadays, since a high refresh rate and high resolution TFT-LCD is requested, the on-state current Iₒₙ is necessary to be large. For example, regarding to an a-Si TFT, a width-length rate (W/L) of a channel can be increased to increase the on-state current Ion.

In a conventional technology, a source electrode and a drain electrode are arranged on the same layer, and are formed by a patterning process simultaneously. Further, since a restriction of a dimensional accuracy of a mask plate, a minimum length of the channel can only be 3.5 μm. It is a bottleneck of increasing Iₒₙ by decreasing the length of the channel.

### SUMMARY OF THE INVENTION

The object of the present invention relates to provide an array substrate and a manufacture method of the same, a liquid crystal display panel, and a display device, which is capable of decreasing a length of a channel between a source electrode and a drain electrode as much as possible, thereby increasing a on-state current Iₒₙ of a TFT.

To achieve the above object, aspects of the present invention will be detailed as following.

According to a first aspect of the present invention, an array substrate includes source electrodes and drain electrodes. Further, the source electrodes and the drain electrodes are arranged on different layers.

According to a second aspect of the present invention, in the array substrate, a pattern of a first passivation layer is formed on the source electrodes, and the drain electrodes are formed on the pattern of the first passivation layer.

According to a third aspect of the present invention, specifically, the array substrate includes: a substrate; a pattern of gate electrodes and gate lines which is arranged on the substrate; a gate insulating layer arranged on the substrate where the pattern of the gate electrodes and the gate lines are formed; a pattern of a semiconductor active layer arranged on the gate insulating layer; a pattern of the source electrodes and data lines which is arranged on the substrate where the pattern of the semiconductor active layer is formed; the pattern of the first passivation layer arranged on the substrate where the pattern of the source electrodes and the data lines is formed; a pattern of an ohmic contact layer arranged on the substrate where the pattern of the first passivation layer is formed; a pattern of the drain electrodes arranged on the substrate where the pattern of the ohmic contact layer is formed; a pattern of a second passivation layer arranged on the substrate where the pattern of the drain electrodes are formed, wherein the pattern of the second passivation layer has pixel electrode via holes corresponding to the drain electrodes; and a pattern of pixel electrodes arranged on the substrate where the pattern of the second passivation layer is formed, wherein the pixel electrodes are connected with the drain electrodes by the pixel electrode via holes.

According to a fourth aspect of the present invention, in the array substrate, a pattern of a first passivation layer is formed on the drain electrodes, and the source electrodes are formed on the pattern of the first passivation layer.

According to a fifth aspect of the present invention, specifically, the array substrate includes: a substrate; a pattern of gate electrodes and gate lines which is arranged on the substrate; a gate insulating layer arranged on the substrate where the pattern of the gate electrodes and the gate lines are formed; a pattern of a semiconductor active layer arranged on the gate insulating layer; a pattern of the drain electrodes which is arranged on the substrate where the pattern of the semiconductor active layer is formed; the pattern of the first passivation layer arranged on the substrate where the pattern of the drain electrodes is formed; a pattern of an ohmic contact layer arranged on the substrate where the pattern of the first passivation layer is formed; a pattern of the source electrodes and data lines which is arranged on the substrate where the pattern of the ohmic contact layer is formed; a pattern of a second passivation layer arranged on the substrate where the pattern of the source electrodes and the data lines is formed, wherein the pattern of the second passivation layer has pixel electrode via holes corresponding to the drain electrodes; and a pattern of pixel electrodes arranged on the substrate where the pattern of the second passivation layer is formed, wherein the pixel electrodes are connected with the drain electrodes by the pixel electrode via holes.

According to a sixth aspect of the present invention, in the array substrate, the pattern of the gate electrodes and the gate lines is made from one of Nd, Cr, W, Ti, Ta, Mo, Al and Cu, or is made from an alloy including at least two of Nd, Cr, W, Ti, Ta, Mo, Al and Cu.

According to a seventh aspect of the present invention, in the array substrate, the gate insulating layer is made from SiNₓ, SiO₂, Al₂O₃, AlN, or resin.

According to an eighth aspect of the present invention, in the array substrate, the semiconductor active layer is made from a-Si

According to a ninth aspect of the present invention, in the array substrate, the pattern of the source electrodes and the data lines and the pattern of the drain electrodes are made from one of Nd, Cr, W, Ti, Ta, Mo, Al and Cu, or are made from an alloy including at least two of Nd, Cr, W, Ti, Ta, Mo, Al and Cu.

According to a tenth aspect of the present invention, in the array substrate, the first passivation layer is made from SiO₂ or SiNₓ, and the second passivation layer is made from SiO₂ or SiNₓ.

According to an eleventh aspect of the present invention, in the array substrate, the ohmic contact layer is made from n+a-Si.

According to a twelfth aspect of the present invention, in the array substrate, the pattern of the pixel electrodes is made from ITO or IZO.

According to a thirteenth aspect of the present invention, a liquid crystal display panel includes the array substrate according to any one of the above aspects.

According to a fourteenth aspect of the present invention, a display device includes a liquid crystal display according to the above aspect.

According to a fifteenth aspect of the present invention, in a manufacture method of an array substrate according to any one of the above aspects comprises: forming the source electrodes and the drain electrodes on different layers by two patterning processes.

According to a sixteenth aspect of the present invention, the manufacture method comprises: forming a pattern of initial source electrodes by one patterning process; forming the pattern of the first passivation layer by one patterning process on the substrate where the pattern of the initial source electrodes is formed, and forming the pattern of the source electrodes by etching the initial source electrodes in accordance with the first passivation layer; and forming the pattern of the drain electrodes by one patterning process on the substrate where the pattern of the first passivation layer is formed.

According to a seventeenth aspect of the present invention, the manufacture method comprises: providing the substrate and forming a gate metal layer on the substrate, and forming the pattern of the gate electrodes and the gate lines by a first patterning process; forming the gate insulating layer and the semiconductor active layer on the substrate processed by the first patterning process sequentially, and forming the pattern of the semiconductor active layer by a second patterning process; forming a source-drain metal layer on the substrate processed by the second patterning process, and forming the pattern of the initial source electrodes and the data lines by a third patterning process; forming the first passivation layer on the substrate processed by the third patterning process, forming the pattern of the first passivation layer by a fourth patterning process, and forming the pattern of the source electrodes by etching the initial source electrodes in accordance with the pattern of the first passivation layer; forming the ohmic contact layer on the substrate where the pattern of the source electrodes is formed, and forming the pattern of the ohmic contact layer by a fifth patterning process; forming a source-drain metal layer on the substrate processed by the fifth patterning process, and forming the pattern of the drain electrodes by a sixth patterning process; forming the second passivation layer on the substrate processed by the sixth patterning process, and forming the pattern of the second passivation layer by a seventh patterning process, wherein the pattern of the second passivation layer includes the pixel electrode via holes corresponding to the drain electrodes; and forming a transparent conducting layer on the substrate processed by the seventh patterning process, and forming the pattern of the pixel electrodes by an eighth patterning process, wherein the pixel electrodes are connected with the drain electrodes by the pixel electrode via holes.

According to an eighteenth aspect of the present invention, the manufacture method comprises: forming a pattern of initial drain electrodes by one patterning process; forming the pattern of the first passivation layer by one patterning process on the substrate where the pattern of the initial drain electrodes is formed, and forming the pattern of the drain electrodes by etching the initial drain electrodes in accordance with the first passivation layer; and forming the pattern of the source electrodes by one patterning process on the substrate where the pattern of the first passivation layer is formed.

According to a nineteenth aspect of the present invention, the manufacture method comprises: providing the substrate and forming a gate metal layer on the substrate, and forming the pattern of the gate electrodes and the gate lines by a first patterning process; forming the gate insulating layer and the semiconductor active layer on the substrate processed by the first patterning process sequentially, and forming the pattern of the semiconductor active layer by a second patterning process; forming a source-drain metal layer on the substrate processed by the second patterning process, and forming the pattern of the initial drain electrodes by a third patterning process; forming the first passivation layer on the substrate processed by the third patterning process, forming the pattern of the first passivation layer by a fourth patterning process, and forming the pattern of the drain electrodes by etching the initial drain electrodes in accordance with the pattern of the first passivation layer; forming the ohmic contact layer on the substrate where the pattern of the drain electrodes is formed, and forming the pattern of the ohmic contact layer by a fifth patterning process; forming a source-drain metal layer on the substrate processed by the fifth patterning process, and forming the pattern of the source electrodes and the data lines by a sixth patterning process; forming the second passivation layer on the substrate processed by the sixth patterning process, and forming the pattern of the second passivation layer by a seventh patterning process, wherein the pattern of the second passivation layer includes the pixel electrode via holes corresponding to the drain electrodes; and forming a transparent conducting layer on the substrate processed by the seventh patterning process, and forming the pattern of the pixel electrodes by an eighth patterning process, wherein the pixel electrodes are connected with the drain electrodes by the pixel electrode via holes.

The above aspects obtain effects as followings.

Since the source electrodes and the drain electrodes are formed on different layers by using two patterning processes, a distance between the source electrode and the corresponding drain electrode can be decreased as much as possible. Therefore, the length of the channel between the source electrodes and the drain electrodes can be decreased as much as possible, thereby increasing the on-state current Iₒₙ of the TFT.

### BRIEF DESCRIPTION OF THE DRAWINGS

FIG. 1 is a schematic view showing an array substrate according to a prior art;

FIG. 2 is a schematic view showing a substrate processed by a first patterning process, according to an embodiment of the present invention;

FIG. 3 is a schematic view showing the substrate after a gate insulating layer is formed, according to the embodiment of the present invention;

FIG. 4 is a schematic view showing the substrate processed by a second patterning process, according to the embodiment of the present invention;

FIG. 5 is a schematic view showing the substrate processed by a third patterning process, according to the embodiment of the present invention;

FIG. 6 is a schematic view showing the substrate processed by a fourth patterning process and a first etching, according to the embodiment of the present invention;

FIG. 7 is a schematic view showing the substrate processed by the fourth patterning process and a second etching, according to the embodiment of the present invention;

FIG. 8 is a schematic view showing the substrate processed by a fifth patterning process, according to the embodiment of the present invention;

FIG. 9 is a schematic view showing the substrate processed by a sixth patterning process, according to the embodiment of the present invention;

FIG. 10 is a schematic view showing the substrate processed by a seventh patterning process, according to the embodiment of the present invention; and

FIG. 11 is a schematic view showing the substrate processed by an eighth patterning process, according to the embodiment of the present invention.

### DETAILED DESCRIPTION OF THE PREFERRED EMBODIMENTS

Hereafter, embodiments will be detailed as the drawings to make the technical issue, technical solutions and advantages of the present invention become more apparent.

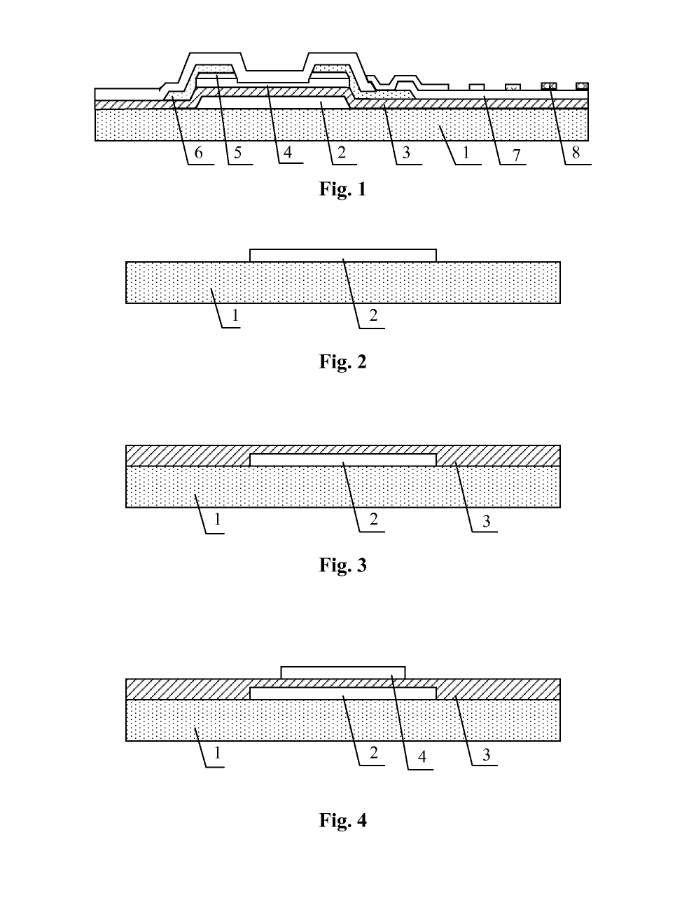

FIG. 1 is a schematic view showing an array substrate according to a prior art. As shown in FIG. 1, a source electrode and a drain electrode are arranged on the same layer, and are formed by a patterning process simultaneously. Since a restriction of a dimensional accuracy of a mask plate, a minimum length of the channel can only be 3.5 μm. It is a bottleneck of increasing Iₒₙ by decrease the length of the channel. To solve the above issue, the embodiments of the present invention provides an array substrate and a manufacture method of the same, a liquid crystal display panel, and a display device, which can decrease a length of a channel between the source electrode and the drain electrode as much as possible, thereby increasing a on-state current Iₒₙ of a TFT.

According to the embodiment of the present invention, the array substrate includes the source electrodes and the drain electrodes. Further, the source electrodes and the drain electrodes are arranged on different layers.

The drain electrodes may be arranged above the source electrodes. Specifically, a pattern of a first passivation layer is formed on the source electrodes, and the drain electrodes are formed on the pattern of the first passivation layer.

Further, the array substrate includes: a substrate; a pattern of gate electrodes and gate lines which is arranged on the substrate; a gate insulating layer arranged on the substrate where the pattern of the gate electrodes and the gate lines are formed; a pattern of a semiconductor active layer arranged on the gate insulating layer; a pattern of the source electrodes and data lines which is arranged on the substrate where the pattern of the semiconductor active layer is formed; the pattern of the first passivation layer arranged on the substrate where the pattern of the source electrodes and the data lines is formed; a pattern of an ohmic contact layer arranged on the substrate where the pattern of the first passivation layer is formed; a pattern of the drain electrodes arranged on the substrate where the pattern of the ohmic contact layer is formed; a pattern of a second passivation layer arranged on the substrate where the pattern of the drain electrodes are formed, wherein the pattern of the second passivation layer has pixel electrode via holes corresponding to the drain electrodes; and a pattern of pixel electrodes arranged on the substrate where the pattern of the second passivation layer is formed, wherein the pixel electrodes are connected with the drain electrodes by the pixel electrode via holes.

Furthermore, the source electrodes may be arranged above the drain electrodes. Specifically, a pattern of a first passivation layer is formed on the drain electrodes, and the source electrodes are formed on the pattern of the first passivation layer.

Further, the array substrate includes: a substrate; a pattern of gate electrodes and gate lines which is arranged on the substrate; a gate insulating layer arranged on the substrate where the pattern of the gate electrodes and the gate lines are formed; a pattern of a semiconductor active layer arranged on the gate insulating layer; a pattern of the drain electrodes which is arranged on the substrate where the pattern of the semiconductor active layer is formed; the pattern of the first passivation layer arranged on the substrate where the pattern of the drain electrodes is formed; a pattern of an ohmic contact layer arranged on the substrate where the pattern of the first passivation layer is formed; a pattern of the source electrodes and data lines which is arranged on the substrate where the pattern of the ohmic contact layer is formed; a pattern of a second passivation layer arranged on the substrate where the pattern of the source electrodes and the data lines is formed, wherein the pattern of the second passivation layer has pixel electrode via holes corresponding to the drain electrodes; and a pattern of pixel electrodes arranged on the substrate where the pattern of the second passivation layer is formed, wherein the pixel electrodes are connected with the drain electrodes by the pixel electrode via holes.

Furthermore, in the array substrate, the pattern of the gate electrodes and the gate lines (gate metal layer) may be made from one of Nd, Cr, W, Ti, Ta, Mo, Al and Cu, or may be made from an alloy including at least two of Nd, Cr, W, Ti, Ta, Mo, Al and Cu. The gate insulating layer may be made from SiNₓ, SiO₂, Al₂O₃, AlN, or resin. The semiconductor active layer may be made from a-Si. The pattern of the source electrodes and the data lines and the pattern of the drain electrodes (source-drain metal layer) may be made from one of Nd, Cr, W, Ti, Ta, Mo, Al, and Cu, or may be made from an alloy including at least two of Nd, Cr, W, Ti, Ta, Mo, Al, and Cu. The first passivation layer may be made from SiO₂ or SiNₓ, and the second passivation layer may be made from SiO₂ or SiNₓ. The ohmic contact layer may be made from n+a-Si. The pattern of the pixel electrodes (transparent conducting layer) may be made from ITO or IZO.

In the embodiments of the present invention, since the source electrodes and the drain electrodes are formed on different layers by two patterning processes, a distance between the source electrode and the corresponding drain electrode can be decreased as much as possible. Therefore, the length of the channel between the source electrode and the drain electrode can be decreased as much as possible, thereby increasing the on-state current Iₒₙ of the TFT.

In a manufacture method of an array substrate according to the embodiment of the present invention comprises: forming the source electrodes and the drain electrodes on different layers by two patterning processes.

Furthermore, the source electrodes may be formed before the drain electrodes are formed. Specifically, the manufacture method may comprise: forming a pattern of initial source electrodes by one patterning process; forming the pattern of the first passivation layer by one patterning process on the substrate where the pattern of the initial source electrodes is formed, and forming the pattern of the source electrodes by etching the initial source electrodes in accordance with the first passivation layer; and forming the pattern of the drain electrodes by one patterning process on the substrate where the pattern of the first passivation layer is formed.

More specifically, the manufacture method may comprise: providing the substrate and forming a gate metal layer on the substrate, and forming the pattern of the gate electrodes and the gate lines by a first patterning process; forming the gate insulating layer and the semiconductor active layer on the substrate processed by the first patterning process sequentially, and forming the pattern of the semiconductor active layer by a second patterning process; forming a source-drain metal layer on the substrate processed by the second patterning process, and forming the pattern of the initial source electrodes and the data lines by a third patterning process; forming the first passivation layer on the substrate processed by the third patterning process, forming the pattern of the first passivation layer by a fourth patterning process, and forming the pattern of the source electrodes by etching the initial source electrodes in accordance with the pattern of the first passivation layer; forming the ohmic contact layer on the substrate where the pattern of the source electrodes is formed, and forming the pattern of the ohmic contact layer by a fifth patterning process; forming a source-drain metal layer on the substrate processed by the fifth patterning process, and forming the pattern of the drain electrodes by a sixth patterning process; forming the second passivation layer on the substrate processed by the sixth patterning process, and forming the pattern of the second passivation layer by a seventh patterning process, wherein the pattern of the second passivation layer includes the pixel electrode via holes corresponding to the drain electrodes; and forming a transparent conducting layer on the substrate processed by the seventh patterning process, and forming the pattern of the pixel electrodes by an eighth patterning process, wherein the pixel electrodes are connected with the drain electrodes by the pixel electrode via holes.

Furthermore, the drain electrodes may be formed before the source electrodes are formed. Specifically, the manufacture method may comprise: forming a pattern of initial drain electrodes by one patterning process; forming the pattern of the first passivation layer by one patterning process on the substrate where the pattern of the initial drain electrodes is formed, and forming the pattern of the drain electrodes by etching the initial drain electrodes in accordance with the first passivation layer; and forming the pattern of the source electrodes by one patterning process on the substrate where the pattern of the first passivation layer is formed.

More specifically, the manufacture method may comprise: providing the substrate and forming a gate metal layer on the substrate, and forming the pattern of the gate electrodes and the gate lines by a first patterning process; forming the gate insulating layer and the semiconductor active layer on the substrate processed by the first patterning process sequentially, and forming the pattern of the semiconductor active layer by a second patterning process; forming a source-drain metal layer on the substrate processed by the second patterning process, and forming a pattern of the initial drain electrodes by a third patterning process; forming the first passivation layer on the substrate processed by the third patterning process, forming the pattern of the first passivation layer by a fourth patterning process, and forming the pattern of the drain electrodes by etching the initial drain electrodes in accordance with the pattern of the first passivation layer; forming the ohmic contact layer on the substrate where the pattern of the drain electrodes is formed, and forming the pattern of the ohmic contact layer by a fifth patterning process; forming a source-drain metal layer on the substrate processed by the fifth patterning process, and forming the pattern of the source electrodes and the data lines by a sixth patterning process; forming the second passivation layer on the substrate processed by the sixth patterning process, and forming the pattern of the second passivation layer by a seventh patterning process, wherein the pattern of the second passivation layer includes the pixel electrode via holes corresponding to the drain electrodes; and forming a transparent conducting layer on the substrate processed by the seventh patterning process, and forming the pattern of the pixel electrodes by an eighth patterning process, wherein the pixel electrodes are connected with the drain electrodes by the pixel electrode via holes.

In the manufacture method of the array substrate according to the embodiment of the present invention, since the source electrodes and the drain electrodes are formed on different layers by two patterning processes, the distance between the source electrode and the corresponding drain electrode can be decreased as much as possible. Therefore, the length of the channel between the source electrode and the drain electrode can be decreased as much as possible, thereby increasing the on-state current Iₒₙ of the TFT.

Hereafter, the array substrate and the manufacture method of the same will be described.

### First Embodiment

In the present embodiment, the source electrodes and the drain electrodes are arranged on different layers, and are separately formed by two patterning processes. Further, the source electrodes are formed before the drain electrodes are formed. As shown in FIGS. 2 to 11, the manufacture method of the array substrate includes steps as followings.

At step a1, a substrate 1 is provided, and the gate metal layer 2 is formed on the substrate 1. The pattern of the gate electrodes and the gate lines is formed by the first patterning process.

Specifically, the substrate 1 may be a transparent substrate. As shown in FIG. 2, the gate metal layer 2 is deposited on the substrate 1, and then the pattern of the gate electrodes and the gate lines is formed by the first patterning process. More specifically, the gate metal layer 2 may be deposited on the substrate 1 by a magnetron sputtering. In this case, the gate metal layer 2 may be made from one of Nd, Cr, W, Ti, Ta, Mo, Al and Cu, or may be made from an alloy including at least two of Nd, Cr, W, Ti, Ta, Mo, Al and Cu. Then, a photoresist is coated on the gate metal layer 2, and a mask plate is used to form the pattern of the gate electrodes and the gate lines by an exposure of the photoresist, a development of the photoresist, and an etching of the photoresist.

At step a2, the gate insulating layer 3 and a semiconductor active layer 4 are sequentially formed on the substrate 1 processed by the first patterning process. The pattern of the semiconductor active layer 4 is formed by the second patterning process.

As shown in FIGS. 3 and 4, the gate insulating layer 3 and the semiconductor active layer 4 are sequentially deposited on the substrate 1 having been through step a1. Specifically, the gate insulating layer 3 may be made from SiNₓ, SiO₂, Al₂O₃, AlN, or resin. The semiconductor active layer 4 may be made from a-Si. Then, the pattern of the semiconductor active layer 4 is formed on the gate insulating layer 3 by the second patterning process. As shown in FIG. 3, the gate insulating layer 3 deposited on the substrate 1 forms a flat surface on the substrate 1. Further, a thickness of the gate insulating layer 3 deposited on the substrate 1 having been through step a1 may be a fixed value. Therefore, the gate insulating layer 3 arranged on the substrate 1 has thickness differences, and this condition will not be shown here.

Specifically, a SiNₓ layer is deposited on the substrate 1 having been through step al for example by a Plasma Enhanced Chemical Vapor Deposition (PECVD) method. Then, a-Si layer is deposited by the PECVD method. Then, a photoresist is coated on the a-Si layer, and a mask plate is used to form the pattern of the semiconductor active layer 4 by an exposure of the photoresist, a development of the photoresist, and an etching of the photoresist.

At step a3, the source-drain metal layer 6 is formed on the substrate 1 processed by the second patterning process. The pattern of the initial source electrodes and the data lines is formed by the third patterning process.

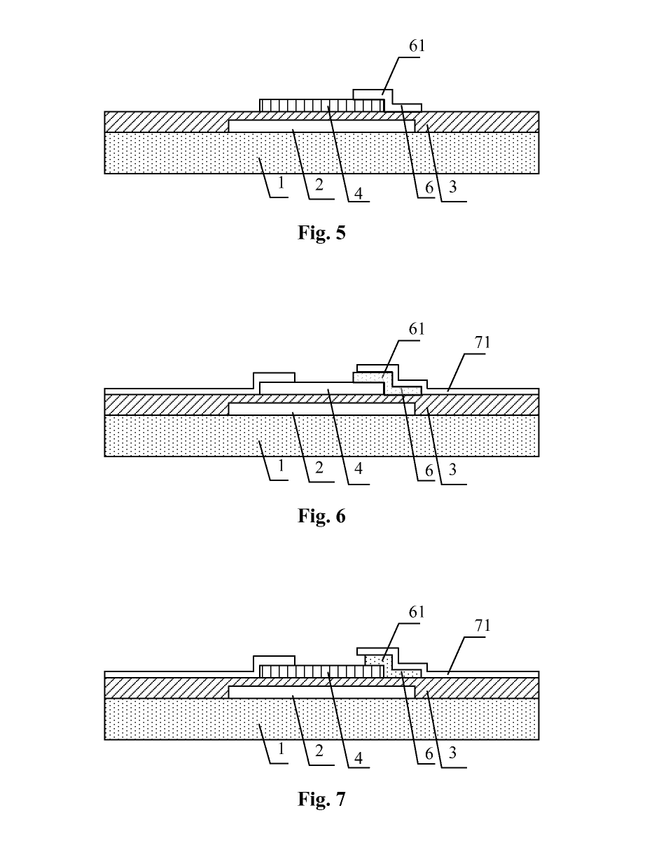

As shown in FIG. 5, the source-drain metal layer 6 may be deposited on the substrate 1 having been through step a2 by the magnetron sputtering. In this case, the source-drain metal layer 6 may be made from one of Nd, Cr, W, Ti, Ta, Mo, Al and Cu, or may be made from an alloy including at least two of Nd, Cr, W, Ti, Ta, Mo, Al and Cu. Then, a photoresist is coated on the source-drain metal layer 6, and a mask plate is used to form the pattern of the initial source electrodes and the data lines by an exposure of the photoresist, a development of the photoresist, and an etching of the photoresist.

At step a4, the first passivation layer 71 is formed on the substrate 1 processed by the third patterning process. The pattern of the first passivation layer 71 is formed by the fourth patterning process. The pattern of the source electrodes 61 are formed by etching the initial source electrodes in accordance with the pattern of the first passivation layer 71.

As shown in FIG. 6, the PECVD method may be used to deposit the first passivation layer 71 on the substrate 1 having been through step a3. Specifically, the first passivation layer 71 may be made from SiO₂ or SiNₓ. Then, a photoresist is coated on the first passivation layer 71, and a mask plate is used to form the pattern of the first passivation layer 71 by an exposure of the photoresist, a development of the photoresist, and an etching of the photoresist. Part of the initial source electrodes are not covered by the first passivation layer 71.

As shown in FIG. 7, the pattern of the first passivation layer 71 is used as the mask plate to etch the initial source electrodes again. Preferably, the pattern of the source electrodes 61 is formed by wet etching. Then, the source electrodes 61 are completely covered by the first passivation layer 71, and the initial source electrode arranged at an edge portion of the first passivation layer 71 is also etched.

At step a5, the ohmic contact layer 5 is formed on the substrate 1 where the pattern of the source electrodes 61 is formed. The pattern of the ohmic contact layer 5 is formed by the fifth patterning process.

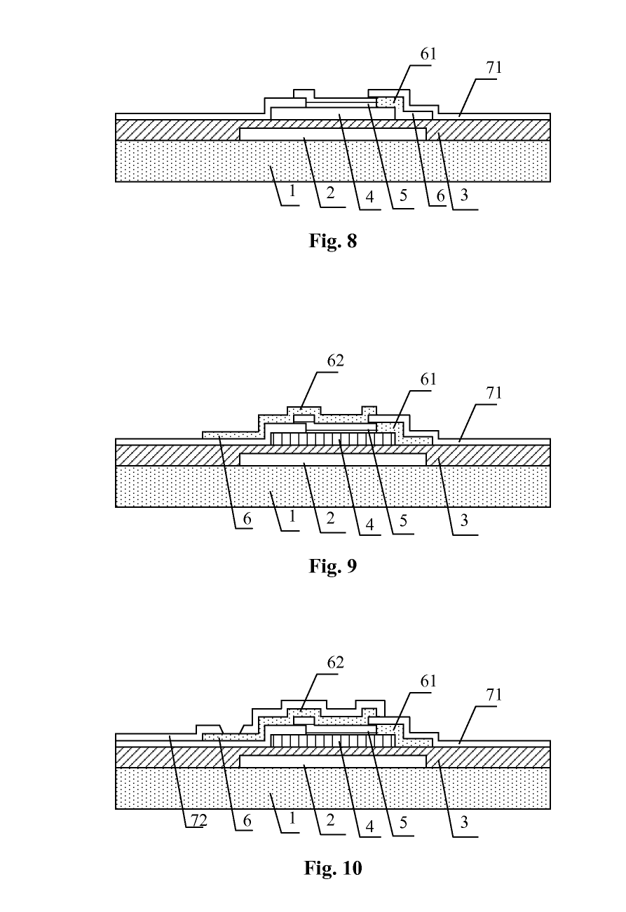

As shown in FIG. 8, the ohmic contact layer 5 is deposited on the substrate 1 having been through step a4. Specifically, the ohmic contact layer 5 may be made from n+a-Si. The PECVD method may be used to deposit an n+a-Si layer on the substrate 1 having been through step a4. Then, a photoresist is coated on the n+a-Si layer, and a mask plate is used to form the pattern of the ohmic contact layer 5 by an exposure of the photoresist, a development of the photoresist, and an etching of the photoresist.

At step a6, the source-drain metal layer 6 is formed on the substrate 1 processed by the fifth patterning process. The pattern of the drain electrodes 62 is formed by the sixth patterning process.

As shown in FIG. 9, the source-drain metal layer 6 may be deposited on the substrate 1 having been through step a5 by the magnetron sputtering. In this case, the source-drain metal layer 6 may be made from one of Nd, Cr, W, Ti, Ta, Mo, Al and Cu, or may be made from an alloy including at least two of Nd, Cr, W, Ti, Ta, Mo, Al and Cu. Then, a photoresist is coated on the source-drain metal layer 6, and a mask plate is used to form the pattern of the drain electrodes 62 by an exposure of the photoresist, a development of the photoresist, and an etching of the photoresist.

As shown in FIG. 9, the drain electrodes 62 and the source electrodes 61 are arranged on different layers, and are separated only by the first passivation layer 71. Therefore, the length of the channel between the drain electrodes 62 and the source electrodes 61 is greatly decreased. For example, the length may be decreased to a length from 1 μm to 1.5 μm. In this case, the on-state current Iₒₙ can be increased by 200% to 350%.

At step a7, the second passivation layer 72 is formed on the substrate 1 processed by the sixth patterning process. The pattern of the second passivation layer 72 is formed by the seventh patterning process. The pattern of the second passivation layer 72 includes the pixel electrode via holes corresponding to the drain electrodes 62.

As shown in FIG. 10, the PECVD method may be used to deposit the second passivation layer 72 on the substrate 1 having been through step a6. Specifically, the second passivation layer 72 may be made from SiO₂ or SiNₓ. Then, a photoresist is coated on the second passivation layer 72, and a mask plate is used to form the pattern of the second passivation layer 72 by an exposure of the photoresist, a development of the photoresist, and an etching of the photoresist. The pattern of the second passivation layer 72 includes the pixel electrode via holes corresponding to the drain electrodes 62.

At step a8, the transparent conducting layer 8 is formed on the substrate 1 processed by the seventh patterning process. The pattern of the pixel electrodes is formed by the eighth patterning process. The pixel electrodes are connected with the drain electrodes 62 by the pixel electrode via holes.

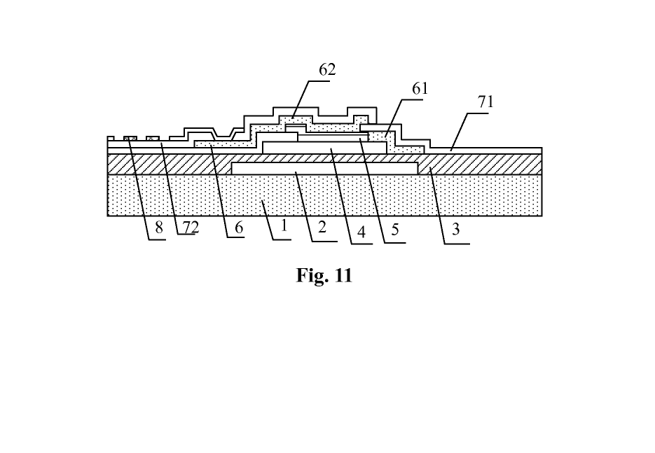

As shown in FIG. 11, the transparent conducting layer 8 may be deposited on the substrate 1 having been through step a7 by the magnetron sputtering. In this case, the transparent conducting layer 8 may be made from ITO or IZO. Then, a photoresist is coated on the transparent conducting layer 8, and a mask plate is used to form the pattern of the pixel electrodes by an exposure of the photoresist, a development of the photoresist, and an etching of the photoresist. The pixel electrodes are connected with the drain electrodes 62 by the pixel electrode via holes.

According to the present embodiment, the source electrodes are formed by the patterning process before the drain electrodes are formed by the patterning process. Since the source electrodes and the drain electrodes are arranged on different layers, the distance between the source electrode and the corresponding drain electrode can be decreased as much as possible. For example, the length of the channel may be decreased to a length from 1 μm to 1.5 μm. Thus, the on-state current Iₒₙ of the TFT is greatly increased.

### Second Embodiment

In the present embodiment, the source electrodes and the drain electrodes are arranged on different layers, and are separately formed by the two patterning processes. Further, the drain electrodes are formed before the source electrodes are formed. The manufacture method of the array substrate includes steps as followings.

At step b1, a substrate is provided, and the gate metal layer is formed on the substrate. The pattern of the gate electrodes and the gate lines is formed by the first patterning process.

Specifically, the substrate may be a transparent substrate. The gate metal layer is deposited on the substrate, and then the pattern of the gate electrodes and the gate lines is formed by the first patterning process. More specifically, the gate metal layer may be deposited on the substrate by the magnetron sputtering. In this case, the gate metal layer may be made from one of Nd, Cr, W, Ti, Ta, Mo, Al and Cu, or may be made from an alloy including at least two of Nd, Cr, W, Ti, Ta, Mo, Al and Cu. Then, a photoresist is coated on the gate metal layer, and a mask plate is used to form the pattern of the gate electrodes and the gate lines by an exposure of the photoresist, a development of the photoresist, and an etching of the photoresist.

At step b2, the gate insulating layer and the semiconductor active layer are sequentially formed on the substrate processed by the first patterning process. The pattern of the semiconductor active layer is formed by the second patterning process.

The gate insulating layer and the semiconductor active layer are sequentially deposited on the substrate having been through step b1. Specifically, the gate insulating layer may be made from SiNₓ, SiO₂, Al₂O₃, AlN, or resin. The semiconductor active layer may be made from a-Si. Then, the pattern of the semiconductor active layer is formed on the gate insulating layer by the second patterning process.

Specifically, the PECVD method may be used to deposit the SiNₓ layer on the substrate having been through step b1. Then, the PECVD method is used to deposit the a-Si layer. Then, a photoresist is coated on the a-Si layer, and a mask plate is used to form the pattern of the semiconductor active layer by an exposure of the photoresist, a development of the photoresist, and an etching of the photoresist.

At step b3, the source-drain metal layer is formed on the substrate processed by the second patterning process. The pattern of the initial drain electrodes is formed by the third patterning process.

The source-drain metal layer may be deposited on the substrate having been through step b2 by the magnetron sputtering. In this case, the source-drain metal layer may be made from one of Nd, Cr, W, Ti, Ta, Mo, Al and Cu, or may be made from an alloy including at least two of Nd, Cr, W, Ti, Ta, Mo, Al and Cu. Then, a photoresist is coated on the source-drain metal layer, and a mask plate is used to form the pattern of the initial drain electrodes by an exposure of the photoresist, a development of the photoresist, and an etching of the photoresist.

At step b4, the first passivation layer is formed on the substrate processed by the third patterning process. The pattern of the first passivation layer is formed by the fourth patterning process. The pattern of the drain electrodes is formed by etching the initial drain electrodes in accordance with the pattern of the first passivation layer.

The PECVD method may be used to deposit the first passivation layer on the substrate having been through step b3. Specifically, the first passivation layer may be made from SiO₂ or SiNₓ. Then, a photoresist is coated on the first passivation layer, and a mask plate is used to form the pattern of the first passivation layer by an exposure of the photoresist, a development of the photoresist, and an etching of the photoresist. Part of the initial drain electrodes are not covered by the first passivation layer.

The pattern of the first passivation layer is used as the mask plate to etch the initial drain electrodes again. Preferably, the pattern of the drain electrodes is formed by wet etching. Then, the drain electrodes are completely covered by the first passivation layer, and the initial drain electrodes arranged at an edge portion of the first passivation layer is also etched.

At step b5, the ohmic contact layer is formed on the substrate where the pattern of the drain electrodes is formed. The pattern of the ohmic contact layer is formed by the fifth patterning process.

The ohmic contact layer is deposited on the substrate having been through step b4. Specifically, the ohmic contact layer may be made from n+a-Si. The PECVD method may be used to deposit the n+a-Si layer on the substrate having been through step b4. Then, a photoresist is coated on the n+a-Si layer, and a mask plate is used to form the pattern of the ohmic contact layer by an exposure of the photoresist, a development of the photoresist, and an etching of the photoresist.

At step b6, the source-drain metal layer is formed on the substrate processed by the fifth patterning process. The pattern of the source electrodes and the data lines is formed by the sixth patterning process.

The source-drain metal layer may be deposited on the substrate having been through step b5 by the magnetron sputtering. In this case, the source-drain metal layer may be made from one of Nd, Cr, W, Ti, Ta, Mo, Al and Cu, or may be made from an alloy including at least two of Nd, Cr, W, Ti, Ta, Mo, Al and Cu. Then, a photoresist is coated on the source-drain metal layer, and a mask plate is used to form the pattern of the source electrodes and the data lines by an exposure of the photoresist, a development of the photoresist, and an etching of the photoresist.

The drain electrodes and the source electrodes are arranged on different layers after step b6, and are separated only by the first passivation layer. Therefore, the length of the channel between the drain electrodes and the source electrodes is greatly decreased. For example, the length may be decreased to a length from 1 μm to 1.5 μm. In this case, the on-state current Iₒₙ can be increased by 200% to 350%.

At step b7, the second passivation layer is formed on the substrate processed by the sixth patterning process. The pattern of the second passivation layer is formed by the seventh patterning process. The pattern of the second passivation layer includes the pixel electrode via holes corresponding to the drain electrodes.

The PECVD method may be used to deposit the second passivation layer on the substrate having been through step b6. Specifically, the second passivation layer may be made from SiO₂ or SiNₓ. Then, a photoresist is coated on the second passivation layer, and a mask plate is used to form the pattern of the second passivation layer by an exposure of the photoresist, a development of the photoresist, and an etching of the photoresist. The pattern of the second passivation layer includes the pixel electrode via holes corresponding to the drain electrodes.

At step b8, the transparent conducting layer is formed on the substrate processed by the seventh patterning process. The pattern of the pixel electrodes is formed by the eighth patterning process. The pixel electrodes are connected with the drain electrodes by the pixel electrode via holes.

The transparent conducting layer may be deposited on the substrate by the magnetron sputtering having been through step b7. In this case, the transparent conducting layer 8 may be made from ITO or IZO. Then, a photoresist is coated on the transparent conducting layer, and a mask plate is used to form the pattern of the pixel electrodes by an exposure of the photoresist, a development of the photoresist, and an etching of the photoresist. The pixel electrodes are connected with the drain electrodes by the pixel electrode via holes.

According to the present embodiment, the drain electrodes are formed by the patterning process before the source electrodes are formed by the patterning process. Since the source electrodes and the drain electrodes are arranged on different layers, the distance between the source electrode and the corresponding drain electrode can be decreased as much as possible. For example, the length of the channel may be decreased to a length from 1 μm to 1.5 μm. Thus, the on-state current Iₒₙ of the TFT is greatly increased.

Further, the liquid crystal display panel includes the above array substrate.

Furthermore, the display device includes the liquid crystal display. The display device may be any products or parts having a display function, such as a liquid crystal panel, an electronic paper, an OLED panel, a cell phone, a panel computer, a television, a monitor, a laptop, a digital photo frame, or a navigation apparatus.

The preferable embodiments according to the present invention have been described. Although the present invention has been described in detail herein with reference to the preferred embodiments, it should be understood by those skilled in the art that the present invention can be modified and some of the technical features can be equivalently substituted without departing from the spirit and scope of the present invention.

What is claimed is:

1. An array substrate, comprising:
source electrodes; and
drain electrodes, wherein
the source electrodes and the drain electrodes are arranged on different layers.

2. The array substrate according to claim 1, wherein
a pattern of a first passivation layer is formed on the source electrodes, and
the drain electrodes are formed on the pattern of the first passivation layer.

3. The array substrate according to claim 2, comprising:
a substrate;
a pattern of gate electrodes and gate lines which is arranged on the substrate;
a gate insulating layer arranged on the substrate where the pattern of the gate electrodes and the gate lines are formed;
a pattern of a semiconductor active layer arranged on the gate insulating layer;
a pattern of the source electrodes and data lines which is arranged on the substrate where the pattern of the semiconductor active layer is formed;
the pattern of the first passivation layer arranged on the substrate where the pattern of the source electrodes and the data lines is formed;
a pattern of an ohmic contact layer arranged on the substrate where the pattern of the first passivation layer is formed;
a pattern of the drain electrodes arranged on the substrate where the pattern of the ohmic contact layer is formed;
a pattern of a second passivation layer arranged on the substrate where the pattern of the drain electrodes are formed, wherein the pattern of the second passivation layer has pixel electrode via holes corresponding to the drain electrodes; and
a pattern of pixel electrodes arranged on the substrate where the pattern of the second passivation layer is formed, wherein the pixel electrodes are connected with the drain electrodes by the pixel electrode via holes.

4. The array substrate according to claim 1, wherein
a pattern of a first passivation layer is formed on the drain electrodes, and
the source electrodes are formed on the pattern of the first passivation layer.

5. The array substrate according to claim 4, comprising:
a substrate;
a pattern of gate electrodes and gate lines which is arranged on the substrate;
a gate insulating layer arranged on the substrate where the pattern of the gate electrodes and the gate lines are formed;
a pattern of a semiconductor active layer arranged on the gate insulating layer;
a pattern of the drain electrodes which is arranged on the substrate where the pattern of the semiconductor active layer is formed;
the pattern of the first passivation layer arranged on the substrate where the pattern of the drain electrodes is formed;
a pattern of an ohmic contact layer arranged on the substrate where the pattern of the first passivation layer is formed;
a pattern of the source electrodes and data lines which is arranged on the substrate where the pattern of the ohmic contact layer is formed;
a pattern of a second passivation layer arranged on the substrate where the pattern of the source electrodes and the data lines is formed, wherein the pattern of the second passivation layer has pixel electrode via holes corresponding to the drain electrodes; and
a pattern of pixel electrodes arranged on the substrate where the pattern of the second passivation layer is formed, wherein the pixel electrodes are connected with the drain electrodes by the pixel electrode via holes.

6. The array substrate according to claim 3, wherein
the pattern of the gate electrodes and the gate lines is made from one of Nd, Cr, W, Ti, Ta, Mo, Al and Cu, or is made from an alloy including at least two of Nd, Cr, W, Ti, Ta, Mo, Al and Cu,
the gate insulating layer is made from SiNₓ, SiO₂, Al₂O₃, AlN or resin,
the semiconductor active layer is made from a-Si,
the pattern of the source electrodes and the data lines and the pattern of the drain electrodes are made from one of Nd, Cr, W, Ti, Ta, Mo, Al and Cu, or are made from an alloy including at least two of Nd, Cr, W, Ti, Ta, Mo, Al and Cu,
the first passivation layer is made from SiO₂ or SiNₓ,
the second passivation layer is made from SiO₂ or SiNₓ,
the ohmic contact layer is made from n+a-Si, and
the pattern of the pixel electrodes is made from ITO or IZO.

7. The array substrate according to claim 5, wherein
the pattern of the gate electrodes and the gate lines is made from one of Nd, Cr, W, Ti, Ta, Mo, Al and Cu, or is made from an alloy including at least two of Nd, Cr, W, Ti, Ta, Mo, Al and Cu,
the gate insulating layer is made from SiNₓ, SiO₂, Al₂O₃, AlN or resin,
the semiconductor active layer is made from a-Si,
the pattern of the source electrodes and the data lines and the pattern of the drain electrodes are made from one of Nd, Cr, W, Ti, Ta, Mo, Al and Cu, or are made from an alloy including at least two of Nd, Cr, W, Ti, Ta, Mo, Al and Cu,
the first passivation layer is made from SiO₂ or SiNₓ,
the second passivation layer is made from SiO₂ or SiNₓ,
the ohmic contact layer is made from n+a-Si, and
the pattern of the pixel electrodes is made from ITO or IZO.

8. A liquid crystal display panel comprising
an array substrate according to claim 1.

9. A liquid crystal display panel comprising
an array substrate according to claim 2.

10. A liquid crystal display panel comprising
an array substrate according to claim 3.

11. A liquid crystal display panel comprising
an array substrate according to claim 4.

12. A liquid crystal display panel comprising
an array substrate according to claim 5.

13. A liquid crystal display panel comprising
an array substrate according to claim 6.

14. A liquid crystal display panel comprising
an array substrate according to claim 7.

15. A manufacture method of an array substrate according to claim 1, comprising:
forming the source electrodes and the drain electrodes on different layers by two patterning processes.

16. The manufacture method according to claim 15, comprising:
forming a pattern of initial source electrodes by one patterning process;
forming the pattern of the first passivation layer by one patterning process on the substrate where the pattern of the initial source electrodes is formed, and forming the pattern of the source electrodes by etching the initial source electrodes in accordance with the first passivation layer; and
forming the pattern of the drain electrodes by one patterning process on the substrate where the pattern of the first passivation layer is formed.

17. The manufacture method according to claim 16, comprising:
providing the substrate and forming a gate metal layer on the substrate, and forming the pattern of the gate electrodes and the gate lines by a first patterning process;
forming the gate insulating layer and the semiconductor active layer on the substrate processed by the first patterning process sequentially, and forming the pattern of the semiconductor active layer by a second patterning process;
forming a source-drain metal layer on the substrate processed by the second patterning process, and forming the pattern of the initial source electrodes and the data lines by a third patterning process;
forming the first passivation layer on the substrate processed by the third patterning process, forming the pattern of the first passivation layer by a fourth patterning process, and forming the pattern of the source electrodes by etching the initial source electrodes in accordance with the pattern of the first passivation layer;
forming the ohmic contact layer on the substrate where the pattern of the source electrodes is formed, and forming the pattern of the ohmic contact layer by a fifth patterning process;
forming a source-drain metal layer on the substrate processed by the fifth patterning process, and forming the pattern of the drain electrodes by a sixth patterning process;
forming the second passivation layer on the substrate processed by the sixth patterning process, and forming the pattern of the second passivation layer by a seventh patterning process, wherein the pattern of the second passivation layer includes the pixel electrode via holes corresponding to the drain electrodes; and
forming a transparent conducting layer on the substrate processed by the seventh patterning process, and forming the pattern of the pixel electrodes by an eighth patterning process, wherein the pixel electrodes are connected with the drain electrodes by the pixel electrode via holes.

18. The manufacture method according to claim 15, comprising:
forming a pattern of initial drain electrodes by one patterning process;
forming the pattern of the first passivation layer by one patterning process on the substrate where the pattern of the initial drain electrodes is formed, and forming the pattern of the drain electrodes by etching the initial drain electrodes in accordance with the first passivation layer; and
forming the pattern of the source electrodes by one patterning process on the substrate where the pattern of the first passivation layer is formed.

19. The manufacture method according to claim 18, comprising:
providing the substrate and forming a gate metal layer on the substrate, and forming the pattern of the gate electrodes and the gate lines by a first patterning process;
forming the gate insulating layer and the semiconductor active layer on the substrate processed by the first patterning process sequentially, and forming the pattern of the semiconductor active layer by a second patterning process;
forming a source-drain metal layer on the substrate processed by the second patterning process, and forming the pattern of the initial drain electrodes by a third patterning process;
forming the first passivation layer on the substrate processed by the third patterning process, forming the pattern of the first passivation layer by a fourth patterning process, and forming the pattern of the drain electrodes by etching the initial drain electrodes in accordance with the pattern of the first passivation layer;
forming the ohmic contact layer on the substrate where the pattern of the drain electrodes is formed, and forming the pattern of the ohmic contact layer by a fifth patterning process;
forming a source-drain metal layer on the substrate processed by the fifth patterning process, and forming the pattern of the source electrodes and the data lines by a sixth patterning process;
forming the second passivation layer on the substrate processed by the sixth patterning process, and forming the pattern of the second passivation layer by a seventh patterning process, wherein the pattern of the second passivation layer includes the pixel electrode via holes corresponding to the drain electrodes; and
forming a transparent conducting layer on the substrate processed by the seventh patterning process, and forming the pattern of the pixel electrodes by an eighth patterning process, wherein the pixel electrodes are connected with the drain electrodes by the pixel electrode via holes.
